(19) United States
(12) Patent Application Publication
(10) Pub. No.: US 2022/0130584 A1
(43) Pub. Date: Apr. 28, 2022

(54) CIRCUIT STRUCTURE, ELECTRICAL JUNCTION BOX, AND METHOD FOR MANUFACTURING CIRCUIT STRUCTURE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Toshiyuki Tsuchida, Yokkaichi-shi, Mie (JP)

(21) Appl. No.: 17/424,068

(22) PCT Filed: Jan. 14, 2020
(86) PCT No.: PCT/JP2020/000809

§ 371 Date: Jul. 19, 2021

(30) Foreign Application Priority Data
Jan. 24, 2019 (JP) 2019-010131

(51) Int. Cl. H01F 27/02; H02G 3/16; H05K 7/14; H05K 7/20; H01F 27/22

(52) U.S. Cl. CPC H01F 27/02; H02G 3/16; H01F 27/22; H05K 7/20; H05K 7/14

(57) ABSTRACT

A circuit structure includes: a circuit substrate provided with a conductive path and through holes that are electrically connected to the conductive path; a coil apparatus that includes coils 51 including terminal portions and a core made of a magnetic material; a heat dissipation member that includes a housing cavity that houses the coil apparatus, and on which the circuit substrate is laid; and grease that comes into contact with the inner surface of the housing cavity and the coil apparatus, and the terminal portions in the coil apparatus are inserted into the through holes and are soldered thereto.

### CROSS-REFERENCE TO RELATED APPLICATIONS

This application is the U.S. national stage of PCT/JP2020/000809 filed on Jan. 14, 2020, which claims priority of Japanese Patent Application No. JP 2019-010131 filed on Jan. 24, 2019, the contents of which are incorporated herein.

### TECHNICAL FIELD

The technology described in the present specification relates to a circuit structure and an electrical junction box.

### BACKGROUND

An electrical junction box such as a DC-DC converter is mounted in vehicles such as automobiles, and a coil is used as a circuit component of this electrical junction box. In an electrical junction box disclosed in JP 2014-103747A, a frame-like member made of a synthetic resin is placed on the outer periphery portion of a heat dissipation member, a circuit substrate is housed in this frame-like member, and a choke coil is disposed in a portion partitioned by the frame-like member.

Incidentally, another electronic component cannot be implemented in a region where the coil is disposed on the heat dissipation member, and thus a region for implementing another electronic component needs to be secured in the electrical junction box, and it is not easy to reduce the size of the electrical junction box. In particular, if a coil that enables conduction of a large current is mounted in the electrical junction box, the size of the coil increases, resulting in a problem in which a region occupied by the coil increases and the size of the electrical junction box is likely to increase.

The technology described in the present specification has been achieved based on the above circumstances, and an object is to reduce the sizes of a circuit structure and an electrical junction box.

### SUMMARY

A circuit structure described in the present specification includes: a circuit substrate provided with a conductive path and a through hole that is electrically connected to the conductive path; a coil apparatus that includes a coil including a terminal portion and a core made of a magnetic material; a heat dissipation member that includes a housing cavity that houses the coil apparatus, and on which the circuit substrate is laid; and grease that comes into contact with an inner surface of the housing cavity and the coil apparatus, and the terminal portion in the coil apparatus is inserted into the through hole and is soldered.

A method for manufacturing a circuit structure described in the present specification includes: in a state where grease is disposed in a housing cavity formed in a heat dissipation member, housing a coil apparatus that includes a coil and a core made of a magnetic material in the housing cavity so as to come into contact with the grease, and inserting a terminal portion of the coil into a through hole and soldering the terminal portion thereto, the terminal portion being formed in a circuit substrate along with a conductive path and electrically connected to the conductive path.

According to the above configuration, the coil apparatus is housed in the housing cavity of the heat dissipation member, and the grease comes into contact with the inner surface of the housing cavity of the heat dissipation member and the coil apparatus, and thus it is possible to perform positioning of the coil apparatus in the housing cavity using the grease, and heat generated by the coil apparatus can be transferred to the heat dissipation member via the grease. Accordingly, a configuration for fixing the coil apparatus does not necessarily need to be provided outside of the housing cavity, and thus it is possible to increase a region outside of the housing cavity where another component can be implemented. Thus, it is possible to increase the implementation density of components of the circuit structure, and to reduce the size of the circuit structure.

The following aspects are preferable as embodiments of the technology described in the present specification.

Room-temperature curing grease is used as the grease.

With such a configuration, work for curing grease does not necessarily need to be performed, and thus the manufacturing process can be simplified.

The housing cavity includes a bottom surface portion and an inner wall portion that stands upright from the bottom surface portion, and the grease is disposed on the bottom surface portion side in the housing cavity.

With such a configuration, it is possible to easily perform the work of housing the coil apparatus in the housing cavity.

The grease is disposed between the circuit substrate and the heat dissipation member outside of the housing cavity, in addition to being disposed between the inner surface of the housing cavity and the coil apparatus.

With such a configuration, when grease is applied in the housing cavity, grease for adhesion, insulation, and the like between the circuit substrate and the heat dissipation member can be applied, and thus the manufacturing process can be simplified.

The coil is an edgewise coil wound such that a short side of a rectangular wire forms an inner diameter plane, and is wound around an axis that passes through a plane that extends along a surface on the circuit substrate side of the heat dissipation member.

With such a configuration, it is easy to reduce the size of the circuit structure depending on the orientation of the coil apparatus.

The circuit substrate is screwed to the heat dissipation member using a screw in a state where there is a gap between the circuit substrate and the heat dissipation member.

With such a configuration, it is possible to implement a component in the gap between the circuit substrate and the heat dissipation member, and to firmly fix the circuit substrate to the heat dissipation member using a screw.

An electrical junction box that includes the circuit structure and a cover that covers the circuit structure.

### Advantageous Effects of Disclosure

According to the technology described in the present specification, it is possible to reduce the sizes of a circuit structure and an electrical junction box.

### BRIEF DESCRIPTION OF DRAWINGS

FIG. 1 is a cross-sectional view showing an electrical junction box according to a first embodiment.

FIG. 2 is a perspective view showing a circuit structure.

FIG. 3 is a cross-sectional view of the circuit structure.

FIG. 4 is a perspective view showing a circuit substrate.

FIG. 5 is a perspective view showing a heat dissipation member.

FIG. 6 is a perspective view showing a state where grease is applied to upper surfaces of the heat dissipation member.

FIG. 7 is a plan view showing a state where grease is applied to the upper surfaces of the heat dissipation member.

FIG. 8 is a cross-sectional view taken along line A-A in FIG. 7.

FIG. 9 is a perspective view showing a state where a coil apparatus is housed in a housing cavity from the state in FIG. 7.

FIG. 10 is a plan view showing a state where the coil apparatus is housed in the housing cavity from the state in FIG. 7.

FIG. 11 is a cross-sectional view taken along line B-B in FIG. 10.

FIG. 12 is a perspective view showing a state where the circuit substrate is placed on the heat dissipation member from the state in FIG. 10.

FIG. 13 is a cross-sectional view showing an electrical junction box according to a second embodiment.

FIG. 14 is a perspective view showing a circuit structure.

FIG. 15 is a cross-sectional view of the circuit structure.

FIG. 16 is a perspective view showing a heat dissipation member.

FIG. 17 is a cross-sectional view showing a state where a coil apparatus is placed on grease in a housing cavity.

FIG. 18 is a perspective view showing a state where a circuit substrate is placed on boss portions of the heat dissipation member from the state in FIG. 17.

FIG. 19 is a perspective view showing a state where the circuit substrate and the boss portions of the heat dissipation member are screwed from the state in FIG. 18.

### DETAILED DESCRIPTION OF PREFERRED EMBODIMENTS

### First Embodiment

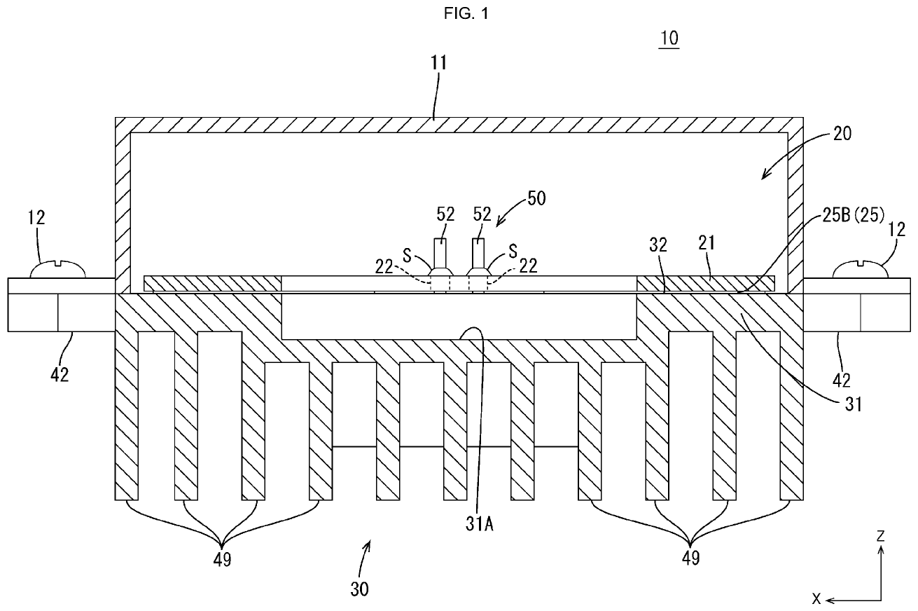

An electrical junction box 10 according to a first embodiment will be described with reference to FIGS. 1 to 12.

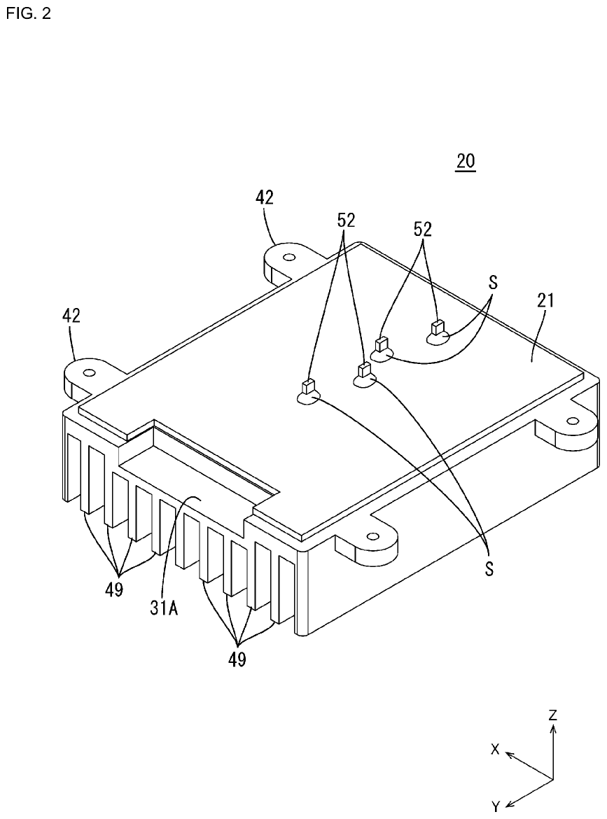

The electrical junction box 10 according to this embodiment is disposed, for example, on a power supply path between a power source such as a battery of a vehicle such as an electric automobile or a hybrid automobile and loads that include in-vehicle electrical components such as lamps and wipers, and a motor, and can be used for a DC-DC converter, an inverter, and the like. In the following description, the X direction in FIG. 1 is defined as a left direction, the Z direction is defined as an upward direction, and the Y direction in FIG. 2 is defined as a forward direction.

As shown in FIG. 1, the electrical junction box 10 includes a circuit structure 20 and a cover 11 that covers the circuit structure 20. The cover 11 is made of metal or a synthetic resin, has a box shape with a lower portion that is open, and is screwed and fixed to a heat dissipation member 30 using screws 12.

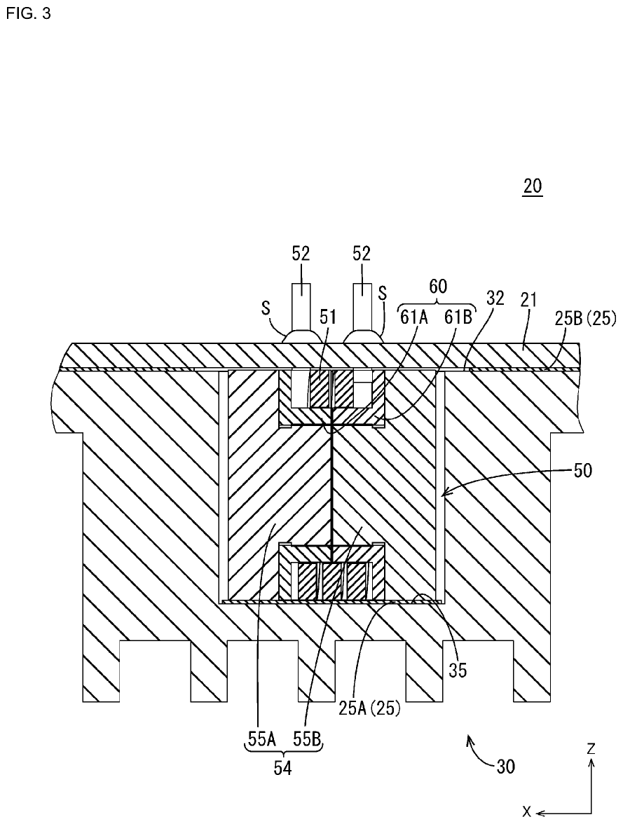

As shown in FIG. 3, the circuit structure 20 includes a circuit substrate 21, the heat dissipation member 30 that dissipates heat generated by the circuit substrate 21 and a coil apparatus 50, grease 25 that is applied over the upper surfaces of the heat dissipation member 30, and the coil apparatus 50 that is housed in a housing cavity 34 of the heat dissipation member 30.

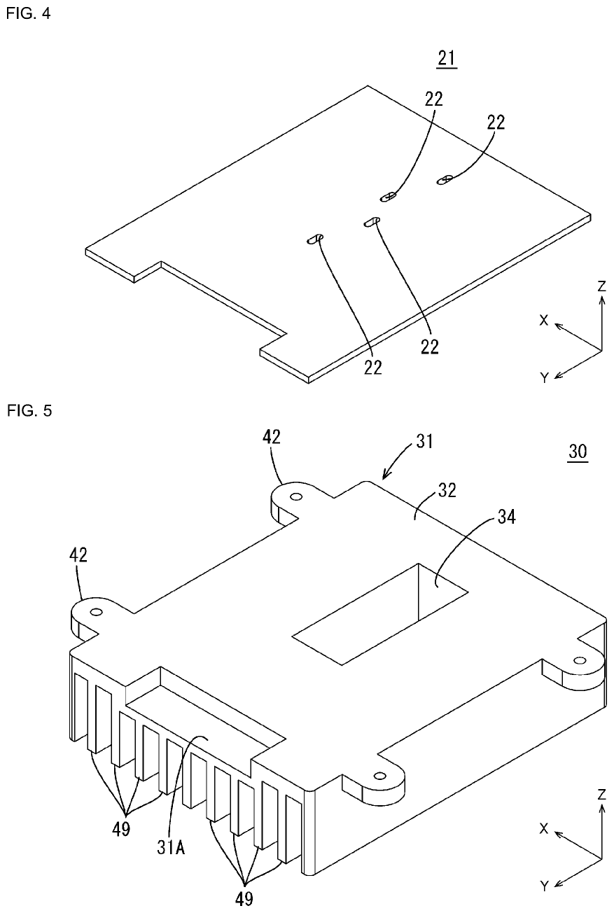

The circuit substrate 21 is a printed board in which a conductive path made of copper foil is formed on an insulation plate made of an insulation material according to a printed wiring technique, and an electronic component (not illustrated) is implemented on the conductive path of the circuit substrate 21. As shown in FIG. 4, on the circuit substrate 21, a plurality of oval through holes 22 that extend through the insulation board are formed at positions continuous with the conductive path. Copper foil is provided over the entirety of the inner surfaces of the through holes 22, and is connected to the conductive path on the upper surface of the circuit substrate 21. Note that the circuit substrate 21 is a printed board, but there is no limitation thereto, and, for example, the circuit substrate may also be formed by laying a busbar made of a metal plate on a printed board. As shown in FIG. 1, the circuit substrate 21 is disposed on the grease 25 applied over a placement surface 32 of the heat dissipation member 30, and is closely attached to the placement surface 32 by using the grease 25.

### Heat Dissipation Member 30

The heat dissipation member 30 is, for example, made of a metal that has a high heat conductivity such as aluminum or aluminum alloy, and is molded through aluminum die casting or the like, and includes a main body 31 on which the circuit substrate 21 is placed, and a plurality of heat-dissipation fins 49 that are continuous in a lower portion of the main body 31 and are aligned in a comb-tooth manner, as shown in FIG. 5.

On the front side of the main body 31, a notch portion 31A in which a connector (not illustrated) that includes a terminal that is connected to the circuit substrate 21 is disposed is formed. The upper surface of the main body 31 is defined as the placement surface 32 on which the circuit substrate 21 is placed in a state where the grease 25 is layered.

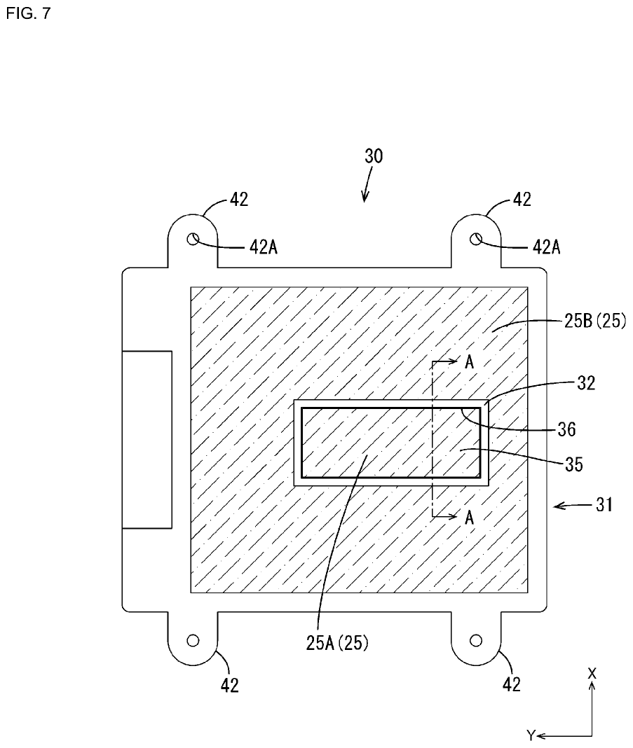

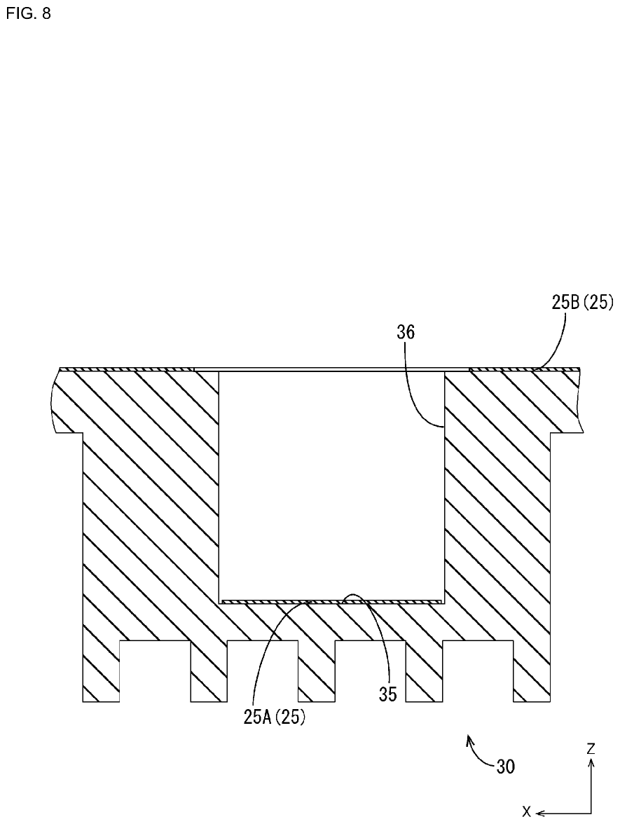

The placement surface 32 is depressed to form the housing cavity 34 that houses the coil apparatus 50. As shown in FIGS. 7 and 8, the housing cavity 34 includes a rectangular bottom surface portion 35 that is elongated in the front-and-rear direction, and an inner wall portion 36 that stands upright from the peripheral edges of the bottom surface portion 35 and is opposed to the outer surface of the coil apparatus 50 so as to enclose the coil apparatus 50, to form a substantially rectangular parallelepiped space in the heat dissipation member 30.

Attachment portions 42 that enable attachment of the cover 11 are provided on the outer periphery of the main body 31. The attachment portions 42 each have a screw hole 42A formed to extend therethrough. As a result of the attachment portions 42 being fixed to the body of a vehicle, for example, the heat dissipation member 30 can be connected to the ground potential.

As shown in FIGS. 7 and 8, the grease 25 includes first grease 25A applied with a predetermined thickness to cover the bottom surface portion 35 of the housing cavity 34 and second grease 25B applied with a predetermined thickness to cover the placement surface 32. In this embodiment, the thickness of the first grease 25A and the thickness of the second grease 25B are substantially the same, but the thickness of the first grease 25A and the thickness of the second grease 25B may be different, and, for example, the thickness of the first grease 25A may be larger than the thickness of the second grease 25B. The grease 25 is obtained by dispersing a viscosity increasing agent in lubricant oil to become semi-solid or solid, and a material that has high heat conductivity and insulation properties is used as the grease 25, and, for example, silicone grease, fluoroether grease, or the like can be used. The grease 25 preferably has a viscosity that is sufficiently high to maintain the position of the coil apparatus 50 placed on the grease 25. The grease 25 preferably has a viscosity that is higher than a liquid adhesive (an adhesive before curing), and grease that cures at a room temperature is preferable. Two liquids of two-liquid silicone heat-dissipation grease that can cure at a room temperature (for example, at 25° C. in several hours) may be mixed, for example. In addition, viscous grease that has increased viscosity obtained by adding an additive substance may also be used.

The coil apparatus 50 is, for example, a choke coil for smoothing an output voltage, and includes a pair of coils 51 (in FIG. 3, only one of the coils 51 is illustrated), a core 54 made of a magnetic material, and a bobbin 60 that holds the coils 51 in the core 54, as shown in FIG. 3. Each of the coils 51 is a so-called edgewise coil, and is formed by winding, in a spiral manner, a band-like rectangular wire that is made of copper, a copper alloy, or the like and has a flattened rectangular cross section, such that short sides respectively form an internal diameter plane and an external diameter plane, and the outer surface is coated with enamel. Each coil 51 includes a pair of terminal portions 52 that extend in the tangent line direction from the end portions of the winding portions in which the wire is wound a plurality of times around a shaft core in a circular manner, and that are connected to an external device. The pair of terminal portions 52 is straight and is arranged parallel to each other. The direction in which the pair of terminal portions 52 extends is a direction orthogonal to the placement surface 32 of the heat dissipation member 30.

The core 54 is formed of a material that has high magnetic permeability such as a ferrite, and is constituted by combining a pair of half bodies 55A and 55B. The half bodies 55A and 55B each include a pair of cylindrical column portions that are inserted into the coils 51, a plate-like connection portion that couples the pair of column portions, and a partition wall that is disposed between the pair of column portions and separates the pair of coils 51 from each other, and these are formed in an integrated manner. The bobbin 60 is made of an insulating synthetic resin, is constituted by a pair of combined division members 61A and 61B, includes cylindrical tube portions into which the column portions of the core 54 are inserted, and maintains the positions of the coils 51 in the core 54.

Next, assembly of the coil apparatus 50 will be described.

The coil apparatus 50 is formed by disposing the coils 51 between the pair of division members 61A and 61B, and combining the pair of half bodies 55A and 55B.

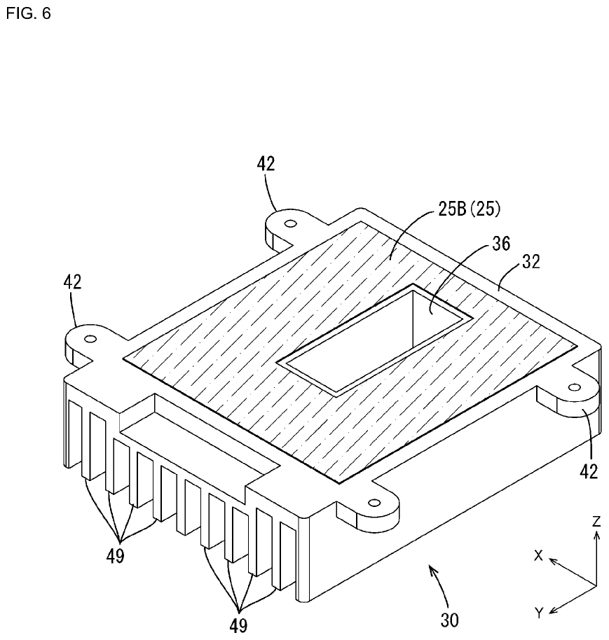

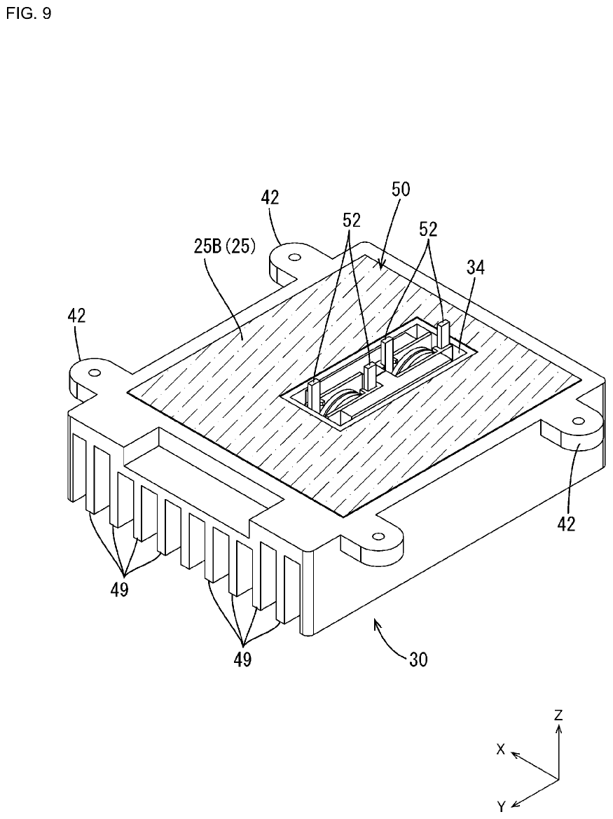

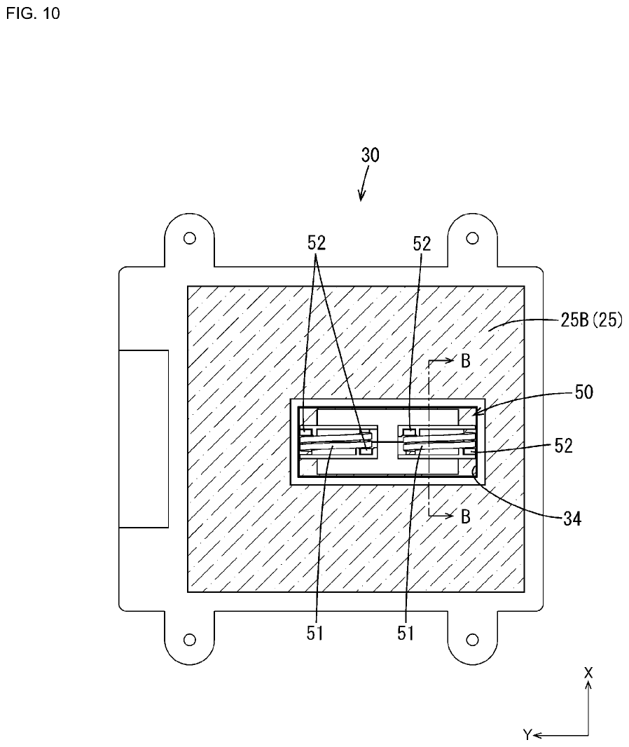

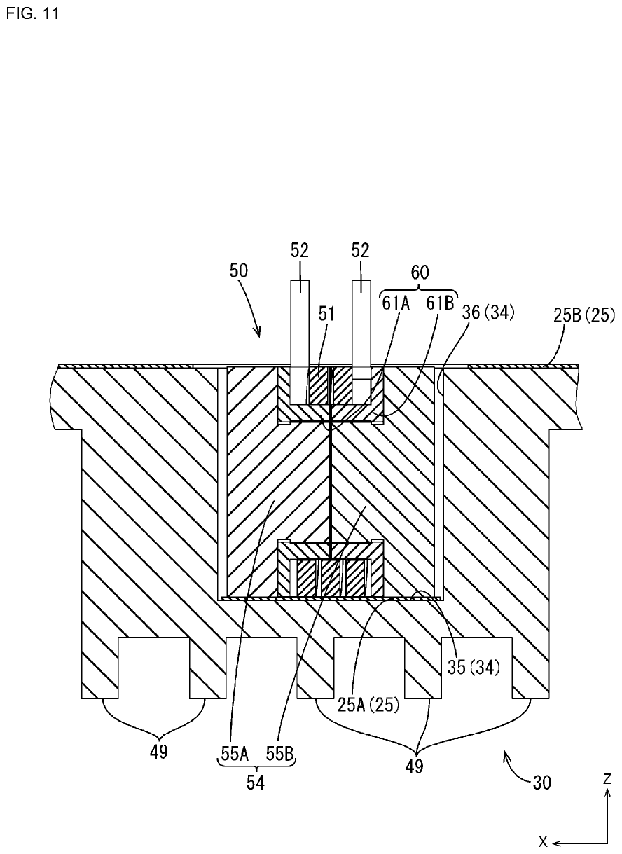

Next, as shown in FIGS. 6 and 7, the grease 25 is applied to the upper surfaces (the bottom surface portion 35 and the placement surface 32) of the heat dissipation member 30. Next, as shown in FIGS. 9 and 10, in the orientation in which all of the terminal portions 52 of the coil apparatus 50 are directed upward, the coil apparatus 50 is inserted into the housing cavity 34 of the heat dissipation member 30. When the coil apparatus 50 is inserted to a predetermined depth in the housing cavity 34, the coil apparatus 50 is placed on the grease 25A (FIG. 11).

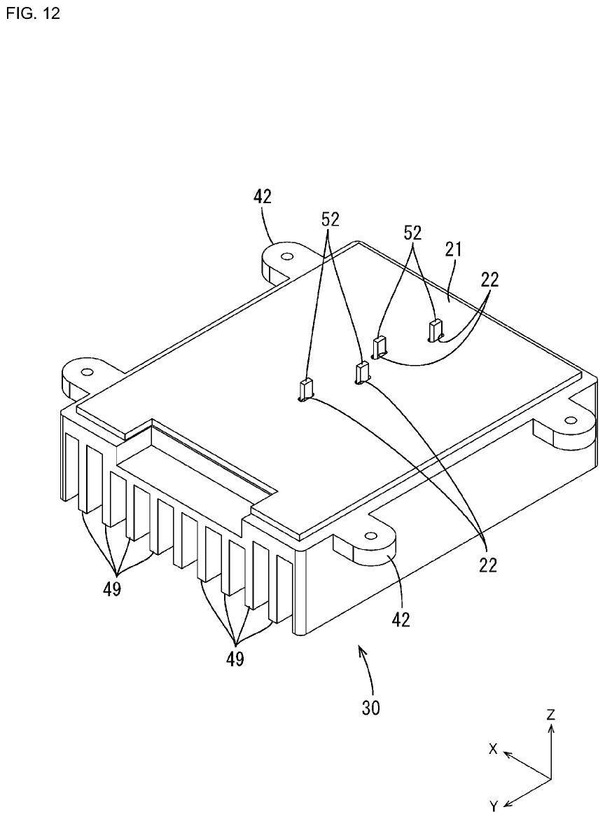

Next, as shown in FIG. 12, the circuit substrate 21 is disposed on the heat dissipation member 30, the terminal portions 52 of the coil apparatus 50 are inserted into the through holes 22 of the circuit substrate 21, and the circuit substrate 21 is placed on the grease 25B of the placement surface 32. Next, as a result of soldering the terminal portions 52 to the through holes 22 of the circuit substrate 21 using solder S, the circuit structure 20 is formed (FIG. 2). As a result of screwing the cover 11 to the circuit structure 20 using the screws 12, the electrical junction box 10 is formed (FIG. 1).

According to this embodiment, the following actions and effects are achieved.

The circuit structure 20 includes: the circuit substrate 21 provided with a conductive path and the through holes 22 that are electrically connected to the conductive path; the coil apparatus 50 that includes the coils 51 including the terminal portions 52 and the core 54 made of a magnetic material; the heat dissipation member 30 that includes the housing cavity 34 that houses the coil apparatus 50, and on which the circuit substrate 21 is laid; and grease 25 that comes into contact with the inner surface of the housing cavity 34 and the coil apparatus 50, and the terminal portions 52 in the coil apparatus 50 are inserted into the through holes 22 and are soldered thereto.

According to this embodiment, since the coil apparatus 50 is housed in the housing cavity 34 of the heat dissipation member 30, and the grease 25 comes into contact with the inner surface of the housing cavity 34 of the heat dissipation member 30 and the coil apparatus 50, it is possible to perform positioning of the coil apparatus 50 in the housing cavity 34 by using the grease 25, and transfer heat generated by the coil apparatus 50 to the heat dissipation member 30 via the grease 25. Accordingly, a configuration for fixing the coil apparatus 50 to the outside of the housing cavity 34 does not necessarily need to be provided, and thus it is possible to increase a region outside of the housing cavity 34 where another component can be implemented. Thus, it is possible to increase the implementation density of components in the circuit structure 20, and reduce the size of the circuit structure 20.

In addition, during manufacturing of the circuit structure 20, before soldering, a state can be set in which the circuit substrate 21 is laid on the heat dissipation member 30 and the terminal portions 52 are inserted into the through holes 22. Accordingly, for example, in contrast to a configuration in which an adhesive is used instead of grease, work for assembling the circuit substrate 21 can be performed after the coil apparatus 50 is housed in the housing cavity 34 without waiting for an adhesive to cure, and thus the manufacturing process can be simplified.

In addition, room-temperature curing grease is used as the grease 25.

With such a configuration, work for curing the grease 25 does not necessarily need to be performed, and thus the manufacturing process can be simplified. In addition, at the time of manufacturing, due to the flexibility of grease, it is possible to reduce stress that acts on the circuit substrate 21 and the like.

In addition, the housing cavity 34 includes the bottom surface portion 35 and the inner wall portion 36 that stands upright from the bottom surface portion 35, and the grease 25 is disposed on the bottom surface portion 35 side in the housing cavity 34.

With such a configuration, it is possible to easily perform work for housing the coil apparatus 50 in the housing cavity 34.

In addition, the grease 25 is disposed between the circuit substrate 21 and the heat dissipation member 30 outside of the housing cavity 34 in addition to between the inner surface of the housing cavity 34 and the coil apparatus 50.

With such a configuration, when the grease 25 is applied in the housing cavity 34, the grease 25 for adhesion, insulation, and the like between the circuit substrate 21 and the heat dissipation member 30 can be applied to the placement surface 32 of the heat dissipation member 30, and thus the manufacturing process can be simplified.

In addition, each of the coils 51 is an edgewise coil wound such that a short side of a rectangular wire forms an inner diameter plane, and is wound around an axis that passes through a surface on the circuit substrate 21 side of the heat dissipation member 30.

With such a configuration, depending on the orientation of the coil apparatus 50, it is easy to reduce the size of the circuit structure 20.

### Second Embodiment

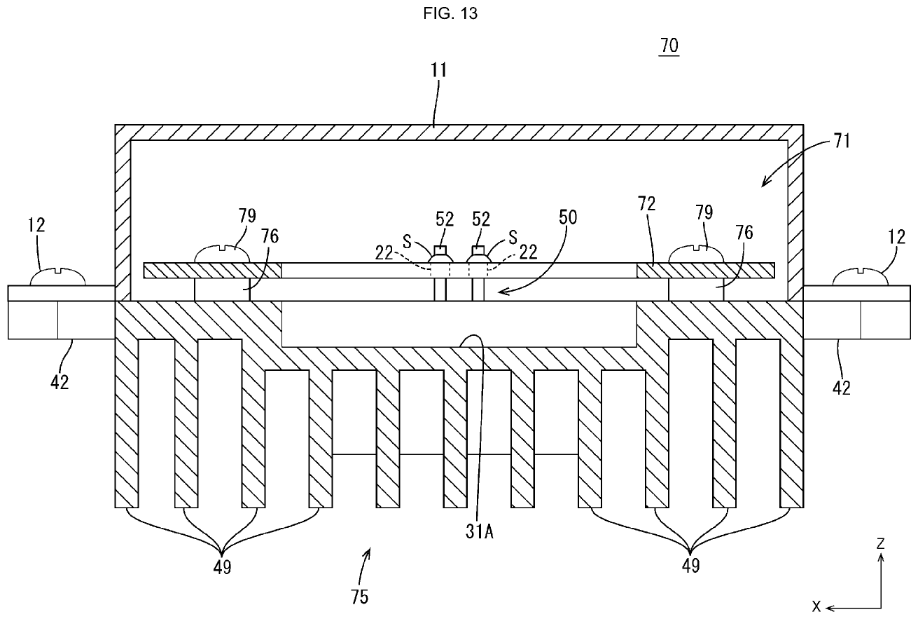

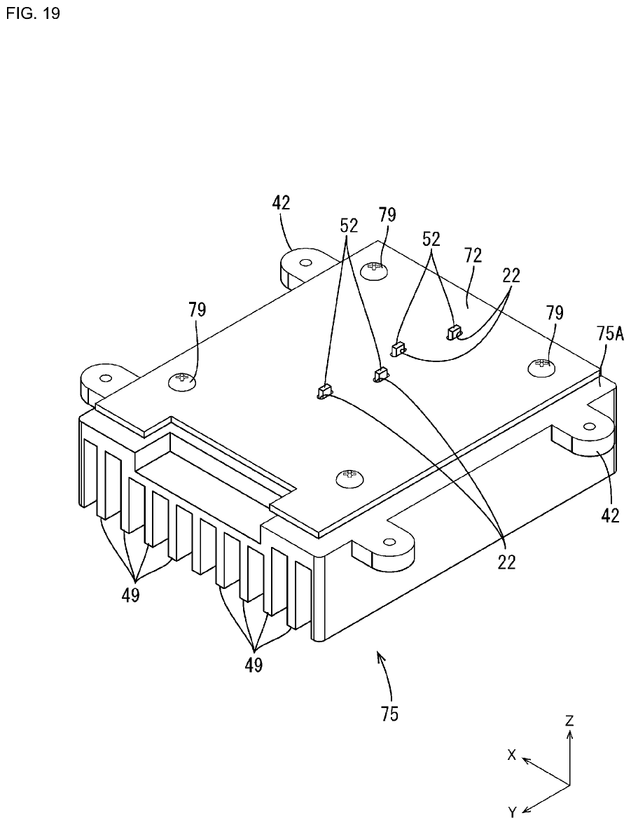

Next, a second embodiment will be described with reference to FIGS. 13 to 19. In the second embodiment, a configuration is adopted in which a circuit substrate 72 is screwed to boss portions 76 of a heat dissipation member 75 using screws 79. In the following description, the same reference numerals are assigned to the same configurations as the first embodiment, and a description thereof is omitted.

As shown in FIG. 13, an electrical junction box 70 includes a circuit structure 71 and the cover 11 that covers the circuit structure 71. The circuit structure 71 includes the circuit substrate 72, the heat dissipation member 75 that dissipates heat generated by the circuit substrate 72 and the coil apparatus 50, and the coil apparatus 50 that is housed in the housing cavity 34 of the heat dissipation member 75.

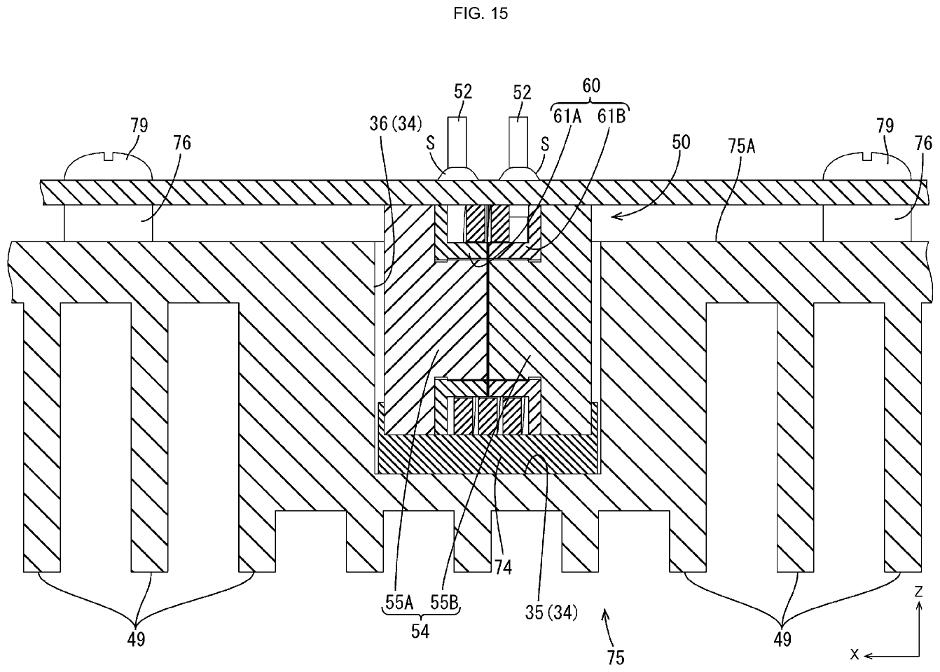

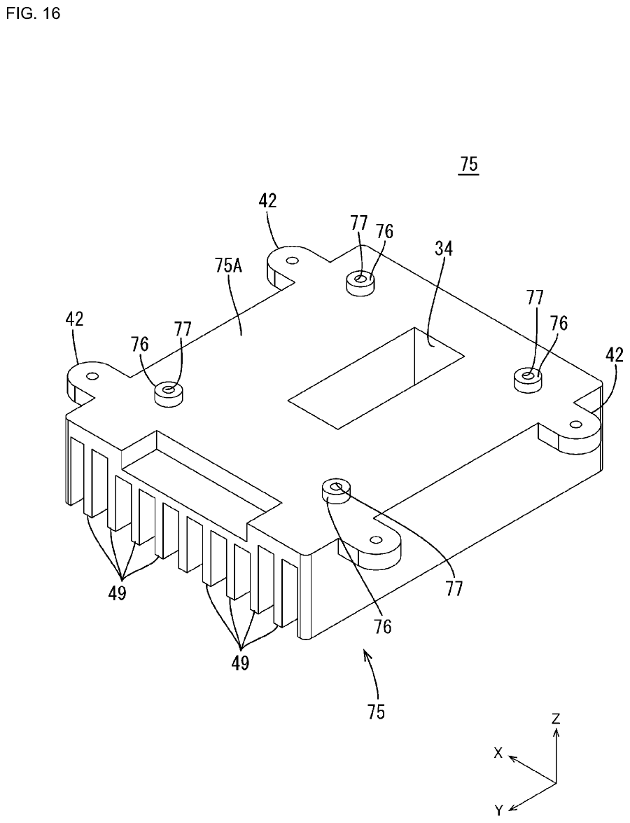

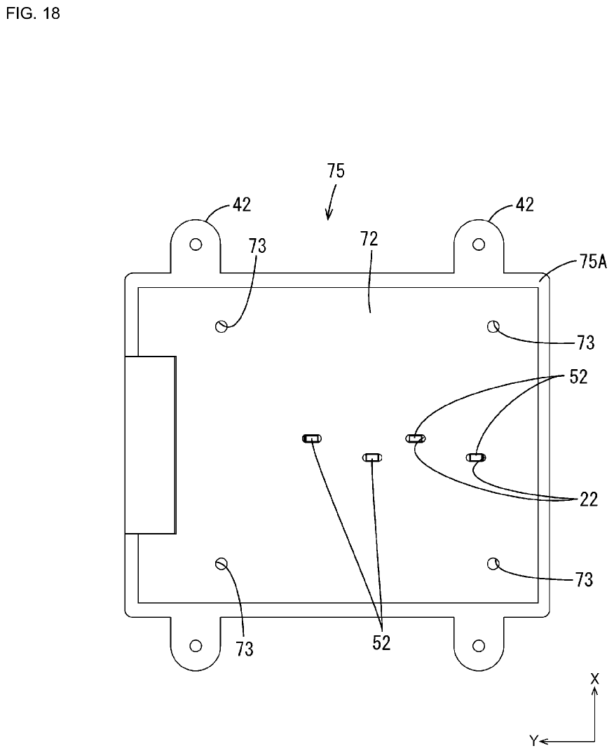

As shown in FIG. 18, on the corner sides of the rectangular circuit substrate 72, a plurality of (in this embodiment, four) through holes 73 are formed to extend through the rectangular circuit substrate 72, and, when screwing the screws, the shaft portions of the screws 79 are inserted into the through holes 73. In addition, as shown in FIG. 16, a plurality of (in this embodiment, four) boss portions 76 are formed in an upper surface 75A of the heat dissipation member 75, at positions corresponding to the through holes 73 of the circuit substrate 72. The boss portions 76 are columnar, and protrude upward (in the axial direction) with a predetermined height from the upper surface 75A. Screw holes 77 for screwing the shaft portions of the screws 79 are formed in the boss portions 76. Note that grease can be applied in a region outside of the housing cavity 34 on the upper surface 75A of the heat dissipation member 75 and on the upper surfaces of the boss portions 76, but grease does not need to be applied. As shown in FIG. 15, grease 74 is disposed with a predetermined thickness on the bottom surface portion 35 of the housing cavity 34, and the grease 74 is in contact with the coil apparatus 50 and the bottom surface portion 35. Grease that is the same as the grease 25 according to the first embodiment may be used as the grease 74.

Next, assembly of the coil apparatus 50 will be described.

As a result of disposing the coils 51 between the pair of division members 61A and 61B and attaching the pair of half bodies 55A and 55B to each other, the coil apparatus 50 is formed.

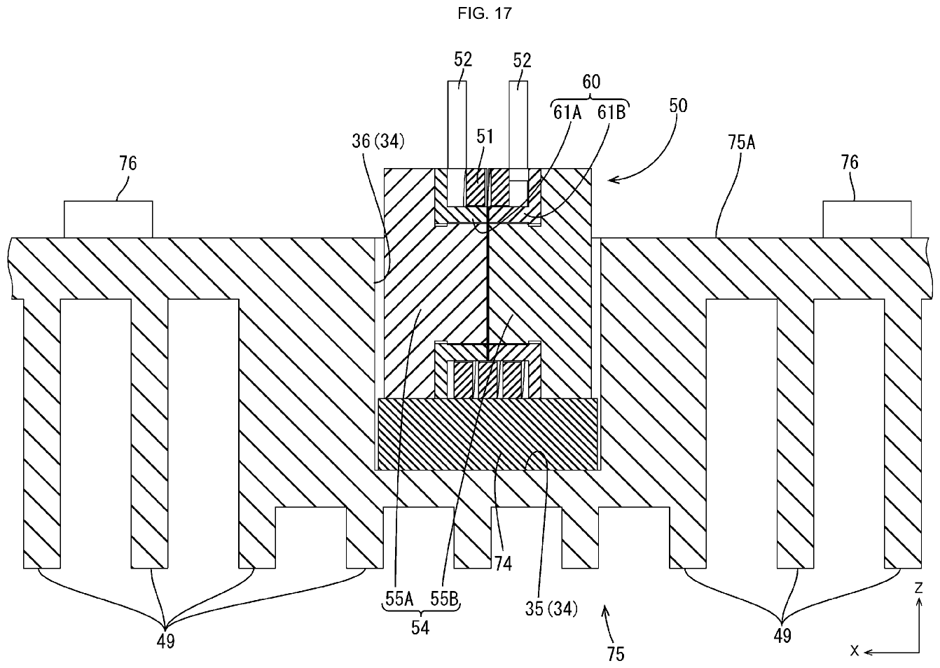

In addition, the grease 25 is applied with a predetermined thickness to the bottom surface portion 35 of the housing cavity 34 of the heat dissipation member 75. Next, in the orientation where all of the terminal portions 52 of the coil apparatus 50 are directed upward, the coil apparatus 50 is inserted into the housing cavity 34 of the heat dissipation member 75. When the coil apparatus 50 is inserted to a predetermined depth in the housing cavity 34, the coil apparatus 50 is placed on the grease 25 as shown in FIG. 17.

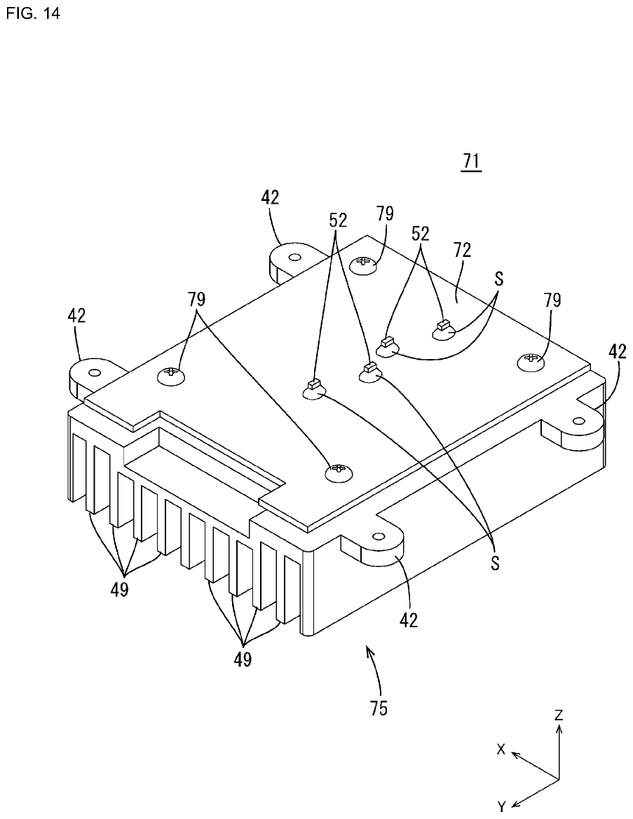

Next, the circuit substrate 72 is disposed on the heat dissipation member 75, and the terminal portions 52 of the coil apparatus 50 are inserted into the through holes 22 of the circuit substrate 72. At this time, for example, when the upper surface of the coil apparatus 50 is positioned higher than the upper surfaces of the boss portions 76 as shown in FIG. 17, a configuration may be adopted in which an upper end portion of the coil apparatus 50 is pressed downward using the circuit substrate 72 so as to embed a lower end portion of the coil apparatus 50 in the grease 25. After the circuit substrate 72 is placed on the boss portions 76, the shaft portions of the screws 79 are inserted into the through holes 73 of the circuit substrate 72 so as to screw the circuit substrate 72 to the boss portions 76. Next, as a result of soldering the terminal portions 52 to the through holes 22 of the circuit substrate 72 using the solder S, the circuit structure 71 is formed (FIG. 14). When the cover 11 is screwed and attached to the circuit structure 71 using the screws 12, the electrical junction box 70 is formed (FIG. 13).

According to the second embodiment, the circuit substrate 72 is screwed to the heat dissipation member 75 using the screws 79 in a state where there is a gap between the circuit substrate 72 and the heat dissipation member 75, and thus a component can be implemented in the gap between the circuit substrate 72 and the heat dissipation member 75, and the circuit substrate 72 can be firmly fixed to the heat dissipation member 75 using the screws 79.

### Other Embodiments

The technology described in the present specification is not limited to the embodiments described above and in the drawings, and for example, the following embodiments are also included in the technical scope of the technology described in the present specification.

A configuration may be adopted in which the grease 25 and the grease 74 are disposed on the bottom surface portion 35 side in the housing cavity 34, but there is no limitation thereto. For example, a configuration may also be adopted in which the grease 25 and the grease 74 are disposed on the inner wall portion 36 side in the housing cavity 34.

A configuration is adopted in which the grease 25 is disposed between the circuit substrate 21 and the heat dissipation member 30 outside of the housing cavity 34 in addition to between the inner surface of the housing cavity 34 and the coil apparatus 50, but there is no limitation thereto. For example, a configuration may also be adopted in which an adhesive is disposed between the circuit substrate 21 and the heat dissipation member 30 in place of the grease 25.

The coils 51 are edgewise coils, but there is no limitation thereto. For example, coils with a circular cross-section may be used as the coils 51.

The coil apparatus 50 is a coupling coil that includes the two coils 51, but there is no limitation thereto. For example, a configuration may also be adopted in which the coil apparatus includes one coil. In addition, the coil apparatus 50 is a choke coil, but there is no limitation thereto, a coil apparatus that is used for other use may also be used.

The number of times each coil 51 is wound is not limited to the above embodiment, and a different number of times may also be adopted.

A configuration is adopted in which the coil apparatus 50 includes the bobbin 60, but there is no limitation thereto, and a coil apparatus that does not include the bobbin 60 may also be used.

1. A circuit structure comprising:
a circuit substrate provided with a conductive path and a through hole that is electrically connected to the conductive path;
a coil apparatus that includes a coil including a terminal portion and a core made of a magnetic material;
a heat dissipation member that includes a housing cavity that houses the coil apparatus, and on which the circuit substrate is laid; and
room-temperature curing grease that comes into contact with an inner surface of the housing cavity and the coil apparatus,
wherein the terminal portion in the coil apparatus is inserted into the through hole and is soldered,
the housing cavity includes a bottom surface portion and an inner wall portion that stands upright from the bottom surface portion,
the grease is disposed on the bottom surface portion side in the housing cavity, and
the grease before curing has a viscosity that is sufficiently high to maintain a position of the coil apparatus placed on the grease, and has a viscosity that is sufficiently high to embed a lower end portion of the coil apparatus in the grease when the coil apparatus is pressed downward.

2. (canceled)

3. (canceled)

4. The circuit structure according to claim 1, wherein the grease is disposed between the circuit substrate and the heat dissipation member outside of the housing cavity, in addition to being disposed between the inner surface of the housing cavity and the coil apparatus.

5. The circuit structure according to claim 1, wherein the coil is an edgewise coil wound such that a short side of a rectangular wire forms an inner diameter plane, and is wound around an axis that passes through a plane that extends along a surface on the circuit substrate side of the heat dissipation member.

6. The circuit structure according to claim 1, wherein the circuit substrate is screwed to the heat dissipation member using a screw in a state where there is a gap between the circuit substrate and the heat dissipation member.

7. An electrical junction box comprising:
the circuit structure according to claim 1; and
a cover that covers the circuit structure.

8. A method for manufacturing a circuit structure comprising:
in a state where room-temperature curing grease is disposed in a housing cavity that is formed in a heat dissipation member and includes a bottom surface portion and an inner wall portion that stands upright from the bottom surface portion, housing a coil apparatus that includes a coil and a core made of a magnetic material in the housing cavity so as to come into contact with the grease; inserting a terminal portion of the coil into a through hole formed in a circuit substrate, the circuit substrate being provided with a conductive path and the through hole that is electrically connected to the conductive path; pressing the coil apparatus so as to embed a lower end portion of the coil apparatus in the grease; and soldering the terminal portion of the coil to the through hole of the circuit substrate.

9. The circuit structure according to claim 4, wherein the coil is an edgewise coil wound such that a short side of a rectangular wire forms an inner diameter plane, and is wound around an axis that passes through a plane that extends along a surface on the circuit substrate side of the heat dissipation member.

10. The circuit structure according to claim 4, wherein the circuit substrate is screwed to the heat dissipation member using a screw in a state where there is a gap between the circuit substrate and the heat dissipation member.

11. The circuit structure according to claim 5, wherein the circuit substrate is screwed to the heat dissipation member using a screw in a state where there is a gap between the circuit substrate and the heat dissipation member.

12. The electrical junction box according to claim 7, wherein the grease is disposed between the circuit substrate and the heat dissipation member outside of the housing cavity, in addition to being disposed between the inner surface of the housing cavity and the coil apparatus.

13. The electrical junction box according to claim 7, wherein the coil is an edgewise coil wound such that a short side of a rectangular wire forms an inner diameter plane, and is wound around an axis that passes through a plane that extends along a surface on the circuit substrate side of the heat dissipation member.

14. The electrical junction box according to claim 7, wherein the circuit substrate is screwed to the heat dissipation member using a screw in a state where there is a gap between the circuit substrate and the heat dissipation member.
